(19) United States
(12) Patent Application Publication
(10) Pub. No.: US 2015/0255194 A1
(43) Pub. Date: Sep. 10, 2015

(54) SELECTION METHOD FOR STRONG WIND REGION COMPOSITE INSULATOR BASED ON INTRINSIC FREQUENCY, AND COMPOSITE INSULATOR

(71) Applicant: GRADUATE SCHOOL AT SHENZHEN, TSINGHUA UNIVERSITY, Shenzhen, Guangdong (CN)

(72) Inventors: Zhidong Jia, Shenzhen (CN); Xilin Wang, Shenzhen (CN); Zhengyi Zhu, Shenzhen (CN); Zhicheng Guan, Shenzhen (CN); Guoxiang Ma, Shenzhen (CN)

(21) Appl. No.: 14/405,779

(22) PCT Filed: Oct. 30, 2013
(86) PCT No.: PCT/CN2013/086266

§ 371 Date: Dec. 4, 2014

(51) Int. Cl. H01B 17/02; G01R 23/02

(52) U.S. Cl. CPC H01B 17/02; G01R 23/02

(57) ABSTRACT

A selection method for a strong wind region composite insulator based on a intrinsic frequency, and a composite insulator are provided. When a selection is made among a plurality of composite insulators according to the selection method, a intrinsic frequency of a composite insulator to be selected is measured first; if the composite insulator is an unequal-diameter umbrella, the intrinsic frequency of a large umbrella skirt in the composite insulator is measured; if the composite insulator is an equal-diameter umbrella, the intrinsic frequency of any umbrella skirt in the composite insulator is measured; and then a composite insulator is selected according to the intrinsic frequency, wherein the composite insulator whose intrinsic frequency is greater than or equal to 45 Hz is selected. The composite insulator is a composite insulator having corresponding structure parameters. Study is carried out on wind-resistant performance of an insulator when applied to a strong wind region to obtain the selection method, and the method is easy to operate and implement. When the composite insulator is applied to a strong wind region where the highest wind speed reaches 50 m/s, the problem of violent oscillation of umbrella skirts or tear of the umbrella skirts does not occur, and the composite insulator may still operate reliably.

### CROSS REFERENCE TO RELATED APPLICATIONS

This application is a national application of PCT/CN2013/086266, filed on Oct. 30, 2013. The contents of PCT/CN2013/086266 are all hereby incorporated by reference.

### FIELD

The present application relates to high voltage and insulation technologies, and particularly to a selection method for a strong wind region composite insulator, and a composite insulator.

### BACKGROUND

Composite insulators are devices often used in high-voltage transmission lines, which are common in towers of transmission lines and high-voltage wire connection towers, for fixing hanging wires, and play a role of electrical insulation between the towers and high-voltage wires. A composite insulator includes a mandrel, a sheath and a plurality of umbrella skirts, and the sheath and the umbrella skirts integrally formed are bonded with the outer side of the mandrel. The mandrel is mainly made from glass fiber, and the sheath and the umbrella skirts are made from high-temperature vulcanized silicone rubber. The silicone rubber has lower modulus of elasticity and soft texture, resulting in that the structure of the umbrella skirts has low stiffness, and thus the umbrella skirts' capability to resist bending and vibration is extremely weak.

The composite insulators are used in outdoor environments, and thus will inevitably encounter strong wind climate environments. For example, in Northwest China, there are eight famous wind regions only in the Xinjiang region. For example, the famous “fifteen-kilometer wind region” between Urumqi and Turpan, the highest average wind speed at a height of 10 m reaches 42 m/s, it is calculated according to a natural wind speed section curve that the highest wind speed at an average nominal height of 46 m of a 750 kV tower reaches 50 m/s, which is a huge challenge for safe operation of the composite insulators: it is mentioned above that, the umbrella skirts of the composite insulators are made from silicone rubber with low modulus of elasticity, resulting in that their capability to resist bending and vibration is weak, and in the strong wind climate environments, the umbrella skirts are prone to a problem that the umbrella skirts violently oscillate under dual effects of wind pressure and flow-induced vibration. Substantial deformation leads to severe stress concentration at the chamfers of the umbrella skirts' root, and long-term cyclic stress effects lead to fatigue and relaxation of silicone rubber materials in the region, which even develop into a tear trouble. Currently, the trouble has become one of the main defensive objects of insulator trouble outside the strong wind region composite insulator, and has caused a great threat to economy and safe operation of the power system.

In the existing selection method, when a selection is made among a plurality of composite insulators, only electrical characteristics of the composite insulators are taken into account. Therefore, in the existing selection method, when a selected composite insulator is used in a strong wind region, it is prone to problems of violent oscillation of umbrella skirts of the insulator and stress concentration at roots of the umbrella skirts, that is, it is prone to root tear troubles caused by the violent oscillation of the umbrella skirts.

### SUMMARY

The technical problem to be solved by some embodiments of the present application is: to make up for the aforementioned deficiencies of the prior art, and a selection method for a strong wind region composite insulator based on a intrinsic frequency, and a composite insulator are provided, where the problem of violent oscillation of umbrella skirts or tear of the umbrella skirts does not occur when the composite insulator is applied to a strong wind region.

The technical problem of the embodiments of the present application is solved through the following technical solution:

a selection method for a strong wind region composite insulator based on a intrinsic frequency, comprising: 1) measuring a intrinsic frequency of a composite insulator to be selected, where, if the composite insulator is an unequal-diameter umbrella, the intrinsic frequency of a large umbrella skirt in the composite insulator is measured; if the composite insulator is an equal-diameter umbrella, the intrinsic frequency of any umbrella skirt in the composite insulator is measured; and 2) selecting a composite insulator according to the intrinsic frequency, wherein the composite insulator whose intrinsic frequency is greater than or equal to 45 Hz is selected.

The technical problem of the embodiments of the present application is solved through a further solution as follows:

a composite insulator, where the intrinsic frequency of the composite insulator is greater than or equal to 45 Hz, where if the composite insulator is an unequal-diameter umbrella, the intrinsic frequency is a intrinsic frequency of a large umbrella skirt in the composite insulator; if the composite insulator is an equal-diameter umbrella, the intrinsic frequency is a intrinsic frequency of any umbrella skirt in the composite insulator.

Compared with the prior art, the embodiments of the present application may have the following beneficial effects:

According to the selection method for a strong wind region composite insulator based on a intrinsic frequency, and the composite insulator of some embodiments of the present application, when a selection is made among a plurality of composite insulators, the selection is made by measuring intrinsic frequencies of the composite insulators and according to certain ranges of the intrinsic frequency, and a selected composite insulator is tested, and it is found that it may withstand strong wind climate environments where the highest wind speed reaches 50 m/s. The present application studies wind-resistant performance of an insulator when applied to a strong wind region to obtain a selection method, the selection method is easy to operate and implement, and when the selected composite insulator is applied to a strong wind region where the highest wind speed reaches 50 m/s, the problem of violent oscillation of umbrella skirts or tear of the umbrella skirts does not occur, and the composite insulator may still operate reliably.

### BRIEF DESCRIPTION OF THE DRAWINGS

FIG. 1 is a schematic diagram showing the structure of a composite insulator in a symmetric umbrella shape according to the present application;

FIG. 2 is a schematic view of a partial longitudinal section of the composite insulator shown in FIG. 1;

FIG. 3 is a flowchart of a selection method for a composite insulator according to the embodiments of the present application; and

FIG. 4 is a curve chart of intrinsic frequencies of seven composite insulators and corresponding oscillation-starting wind speeds in Experiment 1 of the embodiments of the present application.

### DETAILED DESCRIPTION OF THE APPLICATION

The present application is further described below in detail with reference to specific embodiments and the accompanying drawings.

The embodiments of the present application provide a selection method for a strong wind region composite insulator, which makes a selection mainly with respect to wind-resistance issues of the composite insulator in a strong wind region where the highest wind speed reaches 50 m/s, thereby solving the problem of violent oscillation of umbrella skirts of the composite insulator in strong wind environments. Generally, there are many factors affecting violent oscillation of the umbrella skirts, comprising insulator arrangement, an included angle between airflow and an insulator mandrel, a proportion of pulsation components in airflow, a intrinsic frequency of the insulator, material parameters of the insulator and the like. Upon research, it has been found that the most favorable method for solving the problem of violent oscillation of the umbrella skirts is controlling the intrinsic frequency of the insulator. The intrinsic frequency of the insulator comprises overall intrinsic frequencies and local intrinsic frequencies, wherein the former mainly comprises a cooperation manner of large and small umbrellas, an umbrella stretching difference, and an umbrella spacing; the latter mainly comprises an umbrella root chamfer radius, a symmetrical manner of umbrella skirts, an umbrella skirt edge thickness, an umbrella diameter, and an umbrella inclination angle. In the above parameters, the degree of influence varies. After the parameters are improved, the intrinsic frequency of the umbrella skirt also varies. The selection method in the embodiments specifically defines a selection on the intrinsic frequency of the insulator. When the selected composite insulator operates in an environment where the highest wind speed reaches 50 m/s, the umbrella skirts do not oscillate violently, and stress concentration of roots of the umbrella skirts is not significant. The selection method inhibits violent vibration of the umbrella skirts and alleviates stress concentration, so as to achieve the purpose that the umbrella skirts of the composite insulator are not torn in a strong wind region and the composite insulator may operate reliably.

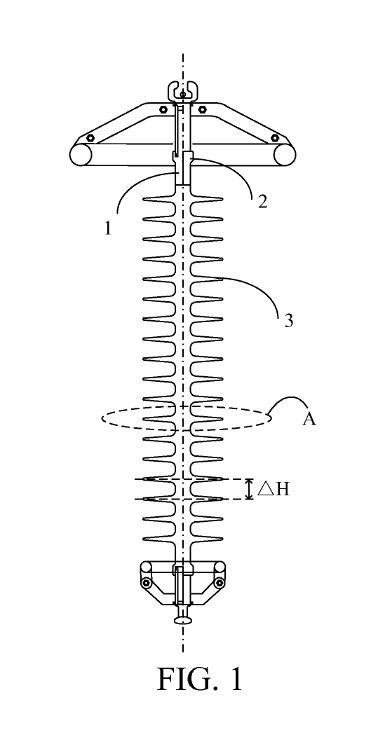

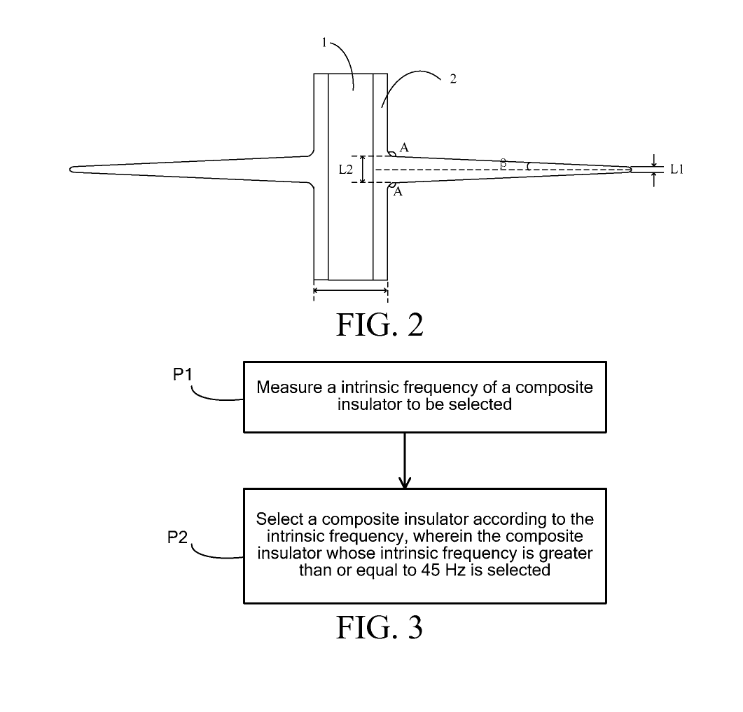

FIG. 1 is a schematic diagram showing the structure of a common composite insulator in a symmetric umbrella shape. The composite insulator includes a mandrel 1, a sheath 2 and a plurality of umbrella skirts 3. The sheath 2 and the umbrella skirts 3 integrally formed are bonded with the outer side of the mandrel 1. A symmetric structure means that upper and lower surfaces of the umbrella skirts are symmetric, and relatively, an asymmetric structure means that upper and lower surfaces of the umbrella skirts are asymmetric. FIG. 2 is a schematic view of a longitudinal section at Part A of the composite insulator shown in FIG. 1, and FIG. 2 shows an umbrella skirt edge thickness L1 and an umbrella skirt root thickness L2, an upper umbrella inclination angle β, and a root chamfer A (a root chamfer radius R exists correspondingly, but is not shown in FIG. 2). In addition, for the structure of the umbrella skirts, there are equal-diameter structures and unequal-diameter structures. The so-called equal-diameter structure means that umbrella skirt diameters of the umbrella skirts in the composite insulator are equal; as shown in FIG. 1, the umbrella skirts are of an equal-diameter structure. Relatively, the unequal-diameter structure means that umbrella skirt diameters of the umbrella skirts in the composite insulator are unequal, and there are large umbrellas and small umbrellas. In the embodiments, for the structure in a symmetric umbrella shape and the structure in an asymmetric umbrella shape or for the equal-diameter structure and the unequal-diameter structure, what the specific parameters are in the structures is not important, and as long as the intrinsic frequency of a corresponding composite insulator at the intrinsic frequency is above 45 Hz, the composite insulator can be selected and applied to a strong wind region, oscillation of the umbrella skirts does not occur, and stress concentration of roots of the umbrella skirts is not significant.

As shown in FIG. 3, FIG. 3 is a flowchart of a selection method for a composite insulator according to the embodiments. The selection method is used for selecting a composite insulator that can be used in a strong wind region (50 m/s) from a plurality of composite insulators to be selected, and even when the selected composite insulator operates in the strong wind region, the umbrella skirts are not torn and the composite insulator may operate reliably. The selection method comprises the following steps.

P1) Measure a intrinsic frequency of a composite insulator to be selected. If the composite insulator is an unequal-diameter umbrella, the intrinsic frequency of a large umbrella skirt in the composite insulator is measured; if the composite insulator is an equal-diameter umbrella, the intrinsic frequency of any umbrella skirt in the composite insulator is measured. In measurement, the intrinsic frequency of an umbrella skirt of an insulator can be measured with a hammering method. During specific measurement, an acceleration sensor is fixed closely to a surface of the umbrella skirt, to hammer the umbrella skirt from different positions, the umbrella skirt vibrates, the acceleration sensor converts a vibration signal into an electrical signal to be input to a processing device, for example, a computer, and the processing device performs Fourier spectrum analysis after collecting the electrical signal, to obtain the intrinsic frequency of the umbrella skirt of the composite insulator.

P2) Select a composite insulator according to the intrinsic frequency, wherein the composite insulator whose intrinsic frequency is greater than or equal to 45 Hz is selected.

The embodiments further provide a composite insulator, wherein the intrinsic frequency of the composite insulator is greater than or equal to 45 Hz. If the composite insulator is an unequal-diameter umbrella, the intrinsic frequency is a intrinsic frequency of a large umbrella skirt in the composite insulator; if the composite insulator is an equal-diameter umbrella, the intrinsic frequency is a intrinsic frequency of any umbrella skirt in the composite insulator.

As follows, oscillation-starting wind speeds of the composite insulators whose intrinsic frequencies are above 45 Hz are verified through experiment setting, so as to verify that the composite insulators can be applied to a strong wind region, and the problems that umbrella skirts violently oscillate and the umbrella skirts are torn do not occur.

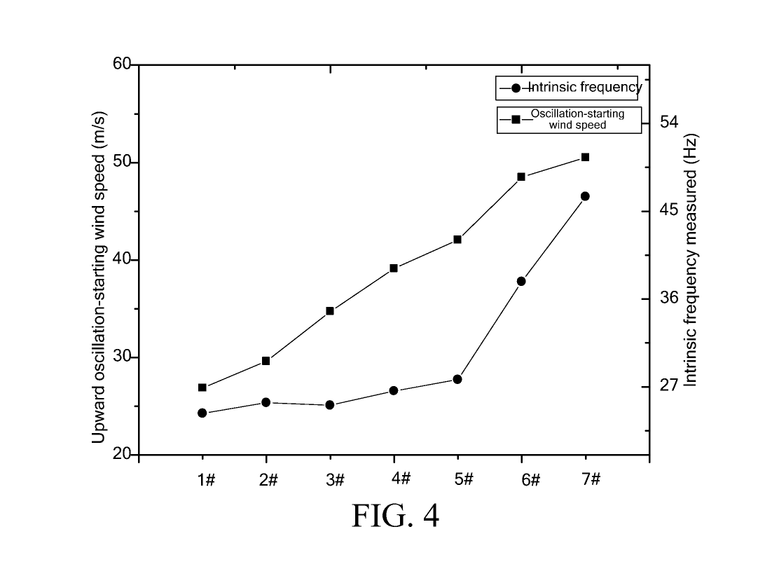

Experiment 1: seven composite insulators having different models and produced by a plurality of manufacturers with a withstanding voltage of 750 kV were selected, which are represented with 1#, 2#, 3#, 4#, 5#, 6#, and 7# separately. Umbrella skirt intrinsic frequency measurement was performed on the seven composite insulators separately, to obtain intrinsic frequencies of the seven composite insulators; wind tunnel experiments were conducted separately, to obtain upward oscillation-starting wind speeds. A curve chart was made on intrinsic frequencies and oscillation-starting wind speeds thereof, as shown in FIG. 4. It can be obtained from FIG. 4 that, only if the intrinsic frequency of the Composite Insulator 7# is greater than 45 Hz, its oscillation-starting wind speed reaches 50 m/s correspondingly. Meanwhile, it can be obtained from FIG. 4 that, the greater the intrinsic frequency of the composite insulator is, the greater the oscillation-starting wind speed thereof is; thus, when the intrinsic frequency of the composite insulator is above 45 Hz, the composite insulator can be applied to a strong wind region (50 m/s), and the problem of tear of umbrella skirts does not occur and the composite insulator may operate reliably when the composite insulator operates in the strong wind region.

Experiment 2: five composite insulators whose intrinsic frequencies are separately 25.1 Hz, 25.38 Hz, 27.73 Hz, 24.28 Hz, and 45.49 H were selected, to test their oscillation-starting wind speeds shown in the following table:

| | | | | | |
|---|---|---|---|---|---|
| Intrinsic frequency (Hz) | 25.1 | 25.38 | 27.73 | 24.28 | 45.49 |
| Oscillation-starting | 29.62 | 34.72 | 42.07 | 26.87 | Still stable |
| wind speed (m/s) | | | | | at 60 m/s |

It can be obtained from the above table that, when the intrinsic frequency of a composite insulator is greater, the oscillation-starting wind speed thereof is also greater. When the intrinsic frequency of the composite insulator is above 45 Hz, the composite insulator can be applied to a strong wind region (50 m/s), and the problem of tear of umbrella skirts does not occur and the composite insulator may operate reliably when the composite insulator operates in the strong wind region.

Preferably, the selection method further comprises step P31) (not shown in the flowchart of FIG. 3): selecting a composite insulator according to the following intrinsic frequency: the composite insulator is of a symmetric umbrella-shaped structure, an umbrella skirt diameter D is 150 mm≦D≦205 mm, an umbrella skirt edge thickness L1 is 3.8 mm≦L1≦6 mm, and an upper umbrella inclination angle β is 3.5°≦β≦8°.

Alternatively, the selection method further comprises step P32) (not shown in the flowchart of FIG. 3): selecting a composite insulator according to the following structure parameters: the composite insulator is of an asymmetric umbrella-shaped structure, an umbrella skirt diameter D is 150 mm≦D≦185 mm, an umbrella skirt edge thickness L1 is 3.8 mm≦L1≦6 mm, and an umbrella skirt root thickness L2 is 13 mm≦L2≦16 mm.

After the composite insulator whose intrinsic frequency is above 45 Hz is selected in steps P1) and P2), the composite insulator with the above structure parameters is selected further according to the preferred steps, and the composite insulator that is selected according to the selection method can be applied to a strong wind region and also facilitates product design and actual manufacturing.

Also preferably, the embodiments provide a composite insulator whose intrinsic frequency is greater than or equal to 45 Hz, and the composite insulator is of a symmetric umbrella-shaped structure, an umbrella skirt diameter D is 150 mm≦D≦205 mm, an umbrella skirt edge thickness L1 is 3.8 mm≦L1≦6 mm, and an upper umbrella inclination angle β is 3.5°≦β≦8°.

Alternatively, the embodiments provide a composite insulator whose intrinsic frequency is greater than or equal to 45 Hz, and the composite insulator is of an asymmetric umbrella-shaped structure, an umbrella skirt diameter D is 150 mm≦D≦185 mm, an umbrella skirt edge thickness L1 is 3.8 mm≦L1≦6 mm, and an umbrella skirt root thickness L2 is 13 mm≦L2≦16 mm.

In this way, as the intrinsic frequencies of the two composite insulators are greater than or equal to 45 Hz, they can be applied to a strong wind region, and the problem of tear of umbrella skirts does not occur and the composite insulators may operate reliably when the composite insulators operate in the strong wind region. Meanwhile, with the structure parameters, the composite insulators facilitate product design and actual manufacturing.

The above content further describes the present application in detail with reference to some embodiments, and it cannot be determined that specific implementation of the present application is merely limited to the descriptions. Several replacements or obvious variations with the same performance or use made by persons of ordinary skill in the art without departing from the concept of the present application should be regarded as falling within the protection scope of the present application.

What is claimed is:

1. A selection method for a strong wind region composite insulator based on a intrinsic frequency, comprising the following steps: 1) measuring a intrinsic frequency of a composite insulator to be selected, wherein, if the composite insulator is an unequal-diameter umbrella, the intrinsic frequency of a large umbrella skirt in the composite insulator is measured; if the composite insulator is an equal-diameter umbrella, the intrinsic frequency of any umbrella skirt in the composite insulator is measured; and 2) selecting a composite insulator according to the intrinsic frequency, wherein the composite insulator whose intrinsic frequency is greater than or equal to 45 Hz is selected.

2. The selection method for a strong wind region composite insulator based on a intrinsic frequency according to claim 1, further comprising step 31): selecting the composite insulator according to the following structure parameters: the composite insulator is of a symmetric umbrella-shaped structure, an umbrella skirt diameter D is 150 mm≦D≦205 mm, an umbrella skirt edge thickness L1 is 3.8 mm≦L1<6 mm, and an upper umbrella inclination angle β is 3.5°≦β≦8°.

3. The selection method for a strong wind region composite insulator based on a intrinsic frequency according to claim 1, further comprising step 32): selecting the composite insulator according to the following structure parameters: the composite insulator is of an asymmetric umbrella-shaped structure, an umbrella skirt diameter D is 150 mm≦D≦185 mm, an umbrella skirt edge thickness L1 is 3.8 mm≦L1≦6 mm, and an umbrella skirt root thickness L2 is 13 mm≦L2≦16 mm.

4. A composite insulator, wherein the intrinsic frequency of the composite insulator is greater than or equal to 45 Hz, wherein, if the composite insulator is an unequal-diameter umbrella, the intrinsic frequency is a intrinsic frequency of a large umbrella skirt in the composite insulator; if the composite insulator is an equal-diameter umbrella, the intrinsic frequency is a intrinsic frequency of any umbrella skirt in the composite insulator.

5. The composite insulator according to claim 4, wherein the composite insulator is of a symmetric umbrella-shaped structure, an umbrella skirt diameter D is 150 mm≦D≦205 mm, an umbrella skirt edge thickness L1 is 3.8 mm≦L1≦6 mm, and an upper umbrella inclination angle β is 3.5°≦β≦8°.

6. The composite insulator according to claim 4, wherein the composite insulator is of an asymmetric umbrella-shaped structure, an umbrella skirt diameter D is 150 mm≦D≦185 mm, an umbrella skirt edge thickness L1 is 3.8 mm≦L1≦6 mm, and an umbrella skirt root thickness L2 is 13 mm<L2<16 mm.
